(19) United States
(12) Patent Application Publication
(10) Pub. No.: US 2020/0259499 A1
(43) Pub. Date: Aug. 13, 2020

(54) CIRCUIT TECHNIQUE TO IMPROVE SPUR-FREE DYNAMIC RANGE OF A DIGITAL TO ANALOG CONVERTER

(71) Applicant: BAE SYSTEMS Information and Electronic Systems Integration Inc., Nashua, NH (US)

(72) Inventor: Randall M. White, Merrimack, NH (US)

(73) Assignee: BAE SYSTEMS Information and Electronic Systems Int egration Inc., Nashua, NH (US)

(21) Appl. No.: 16/273,318

(22) Filed: Feb. 12, 2019

(51) Int. Cl. H03M 1/06; H03M 1/68; H03M 1/78

(52) U.S. Cl. CPC H03M 1/0626; H03M 1/785; H03M 1/68; H03M 1/0614

(57) ABSTRACT

Circuit techniques are disclosed for improving the SFDR of a DAC. In an embodiment, a DAC includes a resistor ladder network operably coupled to input logic circuitry and an output. The input logic circuitry receives a multi-bit input signal and effectively creates a plurality of processed input signals therefrom. The resistor ladder network is configured to receive the plurality of processed input signals and includes a corresponding plurality of current paths. Each current path includes: a current switch operably controlled by one of the processed input signals; a first resistor in series with the current switch; a second resistor in series with the first resistor; and a feedforward capacitor in parallel with the second resistor. The output is operably coupled to each of the plurality of current paths and is configured to output an analog output signal that corresponds to the multi-bit input signal.

### FIELD OF THE DISCLOSURE

This disclosure relates to improved digital to analog conversion, and more specifically to improving the spur-free dynamic range of a digital to analog converter.

### BACKGROUND

An enhancement to a traditional digital to analog converter (DAC) is the R/2R resistor ladder network. This simplified DAC includes only two resistor values: R and 2×R. So, for example, the resistor values can be 25 ohms and 50 ohms. By using only integer ratios of resistor values, the effect of manufacturing variation on the performance of the DAC can be reduced.

When considering DAC design, an important circuit characteristic is the spurious-free dynamic range (SFDR) of the DAC. The SFDR represents the power ratio of the fundamental signal to the strongest spurious signal in the output. For example, in a DAC, the SFDR can be defined as the ratio of the power value of the maximum signal component at the output of the DAC to the power value of the next largest noise or harmonic distortion component at the output. When considering DAC design, a higher SFDR is more desirable.

### BRIEF DESCRIPTION OF THE DRAWINGS

Various aspects of at least one example are discussed below with reference to the accompanying figures, which are not intended to be drawn to scale. The figures are included to provide an illustration and a further understanding of the various aspects and examples and are incorporated in and constitute a part of this specification but are not intended to limit the scope of the disclosure. The drawings, together with the remainder of the specification, serve to explain principles and operations of the described and claimed aspects and examples. For purposes of clarity, not every component may be labeled in every figure.

FIG. 1 depicts a block diagram of an example DAC, according to an embodiment of the present disclosure.

FIG. 2 depicts a circuit diagram of an example DAC including an R/2R resistor ladder network, according to an embodiment of the present disclosure.

FIG. 3 depicts a circuit diagram of an isolated current path through an R/2R resistor ladder network, according to an embodiment of the present disclosure.

FIG. 4 depicts a circuit diagram of an R/2R resistor ladder network including bridging feedforward capacitors, according to an embodiment of the present disclosure.

FIG. 5 depicts a circuit diagram of an R/2R resistor ladder network highlighting potential parasitic elements in the network, according to an embodiment of the present disclosure.

### DETAILED DESCRIPTION

Circuit techniques are disclosed for improving the spur-free dynamic range of a digital to analog converter (DAC). In an embodiment, a DAC includes a resistor ladder network operably coupled to input logic circuitry and an output. The input logic circuitry receives a multi-bit input signal and effectively creates a plurality of processed input signals therefrom. The resistor ladder network is configured to receive the plurality of processed input signals and includes a corresponding plurality of current paths. Each current path includes: a current switch operably controlled by one of the plurality of processed input signals; a first resistor in series with the current switch; a second resistor in series with the first resistor; and a feedforward capacitor in parallel with the second resistor. The output is operably coupled to each of the plurality of current paths and is configured to output an analog output signal that corresponds to the multi-bit input signal. In some such embodiments, the feedforward capacitor is sized to reduce delay through each of the current paths in the resistor ladder network. This in turn may help improve the spur-free dynamic range of the DAC.

General Overview

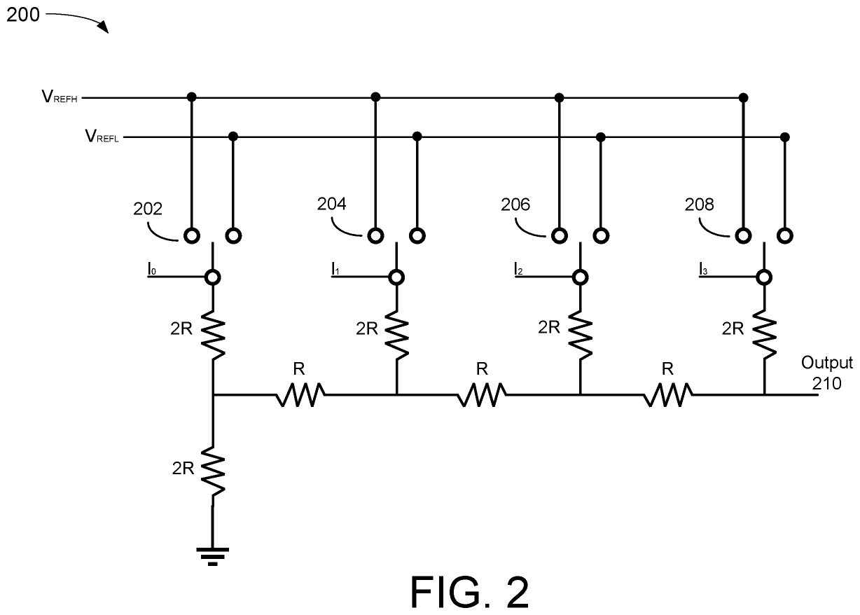

Conventional design of DACs typically includes providing the resistors in the most significant bit (MSB) portion of an R/2R resistor ladder network which are ratio-matched as closely as possible, both with respect to resistance and physical structure, to corresponding resistors in the LSB (least significant bit) portion of the R/2R resistor ladder network. Errors due, for example, to variations in semiconductor processing parameters such as the actual internal resistance and mask/photoresist/etching related processing parameters that occur in the MSB portions of the R/2R resistor ladder network have a much larger effect on the accuracy of the digital-to-analog converter than similar variations in the LSB portion. As the digital-to-analog conversion accuracy depends more on precise resistance ratio matching of the resistances of the “R” and “2R” resistors of an R/2R resistor ladder network than the absolute value of such resistances, improved resistor manufacturing techniques have improved R/2R resistor ladder network design and have reduced the error associated with semiconductor processing parameter variations. However, while improved manufacturing techniques can provide for reduced semiconductor variation, traditional R/2R resistor ladder network architecture still includes various drawbacks, especially in larger DACs (higher resolution, or greater number of input bits, actually makes the DAC physically larger). Additionally, and as will be appreciated in light of this disclosure, a traditional R/2R resistor ladder network design includes a degraded SFDR for some applications, particularly those involving high resolution at high conversion speeds, due to unequal delay and dispersion from each successive bit to the output of the DAC. For example, in a DAC configured to perform high resolution conversion of 7 or 8-bit numbers (e.g., equivalent to 128 or 256 DAC output levels), the physical length of the R/2R resistor ladder network increases linearly (see, for example, FIG. 2 below). For example, the length of an 8-bit R/2R latter is twice as long as a 4-bit R/2R ladder. Increasing the length places a limit on the number of DAC bits that can be usefully and reliably implemented in a traditional R/2R resistor ladder network configuration as the delay for each output bit increases relative to the physical size of the DAC. In a DAC designed to operate at gigahertz sampling rates (e.g., 8 or 16 gigahertz sampling rates), such delay can result in poor linearity due to harmonic distortion at operational speed.

Thus, the techniques and processes as described herein act to mitigate the SFDR degradation due to unequal bit cell delay and dispersion in an R/2R resistor ladder network by bridging one or more of the series R elements with a feed-forward capacitor. In such an arrangement, the R/2R resistor ladder network can be thought of as an RC delay line, with the R value set by the physical resistors of the R/2R resistor ladder network and the C value arising from the associated parasitic capacitance of any component interconnects, resistors, and bit cell switches. When a bridging capacitance comparable to the parasitic C value at each node is connected across each R element, according to some embodiments, the variation in the delay and dispersion of each bit cell to the output is lowered. This approach is especially advantageous, for example, in integrated circuit (IC) process technologies that offer metal-insulator-metal (MIM) capacitors and back end of line (BEOL) resistors as the interconnect between R components and C components can be accomplished with a minimum of parasitic capacitance from lower metal layer interconnects and capacitance to the substrate.

Other possible approaches to address this issue include moving the R/2R resistor ladder network interconnect to a higher metal layer that has a lower parasitic capacitance and a typically thicker geometry. This solution is limited, however, by the IC process technology which may or may not provide thick top metal wiring layers and is not in the circuit designer's control once an IC process has been selected. In contrast, the solution as proposed herein enables the delay problem to be addressed through circuit design techniques rather than IC process technology.

System Architecture

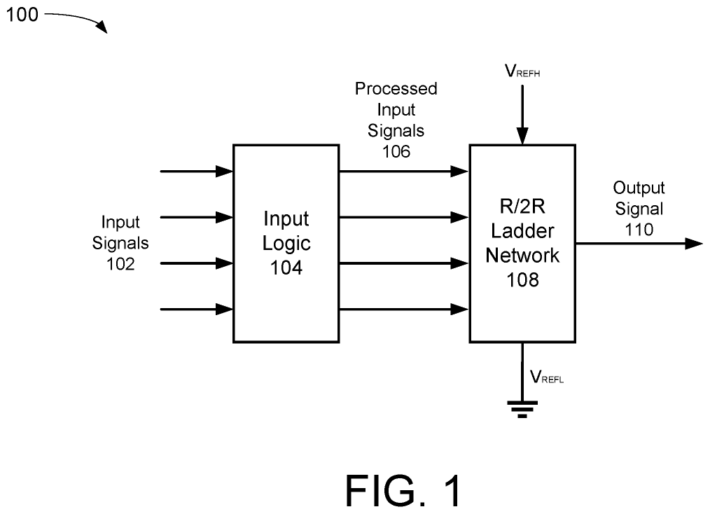

FIG. 1 illustrates a sample DAC 100 configured to convert a digital input signal 102 to an analog output signal 110. The DAC 100 can include, for example, conventional input logic circuitry 104 configured to receive the input signals 102. As shown in this example, the input signal can be configured as a 4-bit digital input signal. However, it should be noted that this is shown by way of example only and various other size inputs such as 3-bit, 4-bit, 5-bit, 6-bit, 7-bit, 8-bit, or any other sized digital input signals can be converted using a DAC as described herein.

In certain implementations, the input logic circuitry 104 can be configured to produce a series of processed input signals 106 which are provided as inputs, for example as switched currents, to an R/2R resistor ladder network 108. For example, the input logic circuitry can be operably coupled to a current switch that is configured to output switched currents to the R/2R resistor ladder network 108. In certain implementations, the processed input signals can be configured in a parallel format, and could, for example, be a binary number. In certain implementations, the input logic 104 can include various latches and drivers to produce the processed input signals 106. In certain implementations, the R/2R resistor ladder network 108 can include an R/2R resistor ladder network designed according to the techniques as described herein to produce an analog output signal 110.

In some examples, the R/2R resistor ladder network 108 can be connected between a high reference voltage V_{REFH} and a low reference voltage V_{REFL} on conductor 12. Additionally, in certain implementations, the output signal 110 can be input into an operational amplifier (not shown in FIG. 1) to scaling the output voltage of the output signal.

FIG. 2 is a diagram illustrating an example 4-bit R/2R resistor ladder network 200 for use in a 4-bit DAC. The R/2R resistor ladder network 200 can be designed to enable the conversion of a parallel digital symbol (e.g., 4-bits 10-13 received as, for example, processed input signal 106 as shown in FIG. 1) into a current or an analog voltage, which may be measured at the output 210. Each of the four digital inputs (I₀-I₃) adds a respective weighted contribution to the analog output 210, and no two different 4-bit words (from 0000 to 1111) can result in an identical current or voltage at the output. A current switch (202, 204, 206, 208) for each of the bits 10-13 may be operated according to whether a value on one of the bits 10-13 is 1 or 0. Accordingly, the value of the digital signal into the DAC can be created by operation of current switches 202-208 that control the bits of the DAC. For example, a bit can correspond to the value “1” for the position of that particular bit within the processed input signal. For that bit, the associated current switch (e.g., current switch 202 for bit I₀) can be in the left position, thereby connecting the leftmost current path as shown in FIG. 2 to the V_{REFH} signal and producing a first current or voltage at output 210. Conversely, if the bit corresponds to a “0”. the current switch can be in the right position, thereby connecting the leftmost current path as shown in FIG. 2 to the V_{REFL} signal which, as shown in FIG. 1, is tied to ground. In such an arrangement, no current or voltage will be contributed to the output 210 for that associated bit. Accordingly, if all the current switches for controlling the bits of the DAC are to the right (e.g., if all four current switches of a four-bit DAC are open to produce a digital symbol of 0000), then no current flows into the resistor ladder, and no current or voltage is produced at the output 210.

Based upon the design of the R/2R resistor ladder network, and the value of V_{REFH}, the value of the output 210 voltage can be measured and, based upon the measured voltage, the value of the input bits 10-13 can be determined. For example, as shown in TABLE 1, a specific output voltage measured at output 210 can correspond to a specific input voltage. It should be noted that the voltage values in TABLE 1 are provided by way of example only and can vary based upon the value of the R and 2R resistors and V_{REFH}.

TABLE 1

| Binary Input | Output Voltage | |
|---|---|---|
| 0000 | 0.000 | V |
| 0001 | −0.0625 | V |
| 0010 | −0.125 | V |
| 0011 | −0.1875 | V |
| 0100 | −0.250 | V |
| 0101 | −0.3125 | V |
| 0110 | −0.375 | V |
| 0111 | −0.4375 | V |
| 1000 | −0.500 | V |
| 1001 | −0.5625 | V |
| 1010 | −0.625 | V |
| 1011 | −0.6875 | V |
| 1100 | −0.750 | V |
| 1101 | −0.8125 | V |
| 1110 | −0.875 | V |
| 1111 | −0.9375 | V |

Referring again to FIG. 2, by continuing the R/2R pattern of the resistor ladder shown 200, an R/2R resistor ladder network can be scaled to any number of bits. Furthermore, as noted above, only two different resistor values are used to construct the R/2R resistor ladder network. For example, if the value of the “R” resistors in FIG. 2 is 25 ohms, then the value of the resistors represented by “2R” is 50 ohms (i.e., twice the value of the resistors represented by “R”). Because only two resistor values are used, the R/2R resistor ladder network may be easily and accurately produced and integrated into a circuit. However, as noted above, by scaling the R/2R resistor ladder network size to accommodate larger numbers of bit (e.g., 7 or 8-bit), added delay can occur which reduces the SFDR degradation of the DAC.

As noted above, when building a fast DAC there are several important considerations. If constructing a sine wave output, harmonic distortion is undesirable. In such an arrangement, having a high SFDR results in a sinusoidal signal having relatively low harmonics that do not interfere with the desired output. When using large DAC operating at high speeds, it is challenging to maintain spectral purity throughout the signal and have a high SFDR. For example, when using a 16-gigahertz sampling rate, it is difficult to maintain a high SFDR and produce an 8-gigahertz output (i.e., the first Nyquist frequency for the sampled signal). Various things can cause signal distortion such as dynamic switching glitches, signal mismatch, and other similar component-based distortions. One of the major contributors is delay and distortion caused by the high frequency signal rates through the R/2R resistor ladder network. When building an R/2R resistor ladder network into a transmission line, the overall R values of the transmission lines become unbalanced due to the parasitic capacitance (in conjunction with, for example, series resistance and any phase shift/delay), resulting in a low-pass response where the series resistors of the R/2R resistor ladder network create a phase shift or some additional delay. The net effect of the sum of these distortion sources is that the current division throughout the R/2R resistor ladder network (from the MSB to the LSB) does not result each of the current paths through the R/2R resistor ladder network reaching the output at the same time. Such an arrangement can reduce the SFDR of a high-speed DAC.

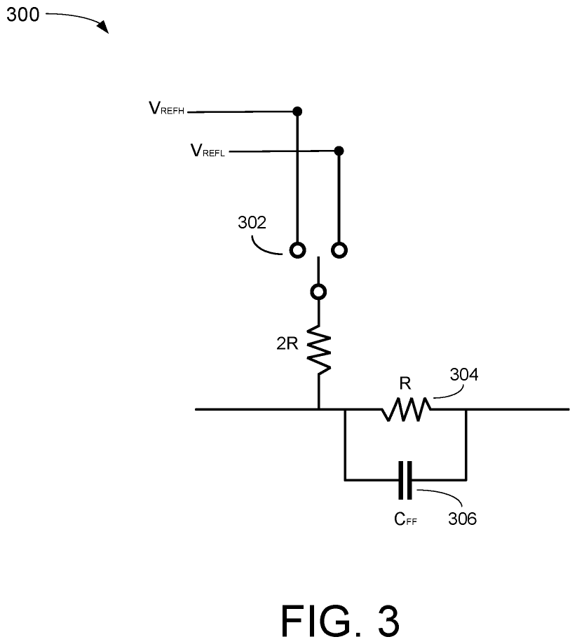

As shown in FIG. 3, the present disclosure teaches using a feedforward capacitor in parallel with each R resistor in the R/2R resistor ladder network to bridge the individual R resistors. By including the feedforward capacitors, delay associated with each bit (e.g., each current path through the R/2R resistor ladder network) arrives at the output at approximately the same time and mitigates any distortion or error associated with signal delay through the R/2R resistor ladder network.

More specifically, as shown in FIG. 3, a single current path 300 from an R/2R resistor ladder network (e.g., resistor ladder network 200 as shown in FIG. 2) is shown. Similar to the discussion above, the current path 300 can include a current switch 302 positioned to alternatively switch between V_{REFH} and V_{REFL} depending upon an input signal to the current switch. If the current switch is connected to V_{REFH}, current can flow through the 2R resistor and then through the R resistor 304 and the feedforward capacitor 306 positioned in parallel to the R resistor 304 and configured to bridge the R resistor. By providing such an arrangement, the feedforward capacitor 306 can be used to tune frequency response of the current path 300, thereby providing a propagation delay through the current path similar to those through other current paths in the R/2R resistor ladder network.

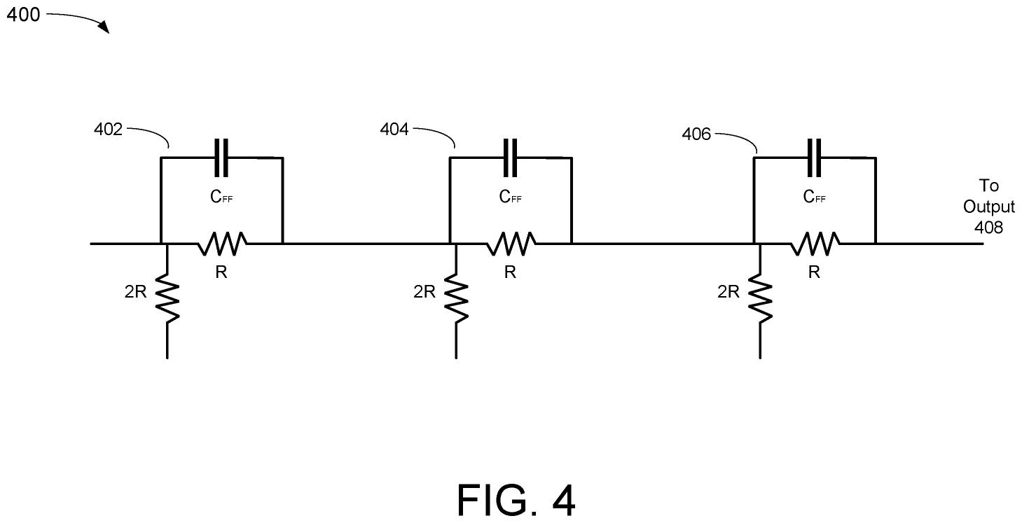

FIG. 4 illustrates a multi-bit R/2R resistor ladder network 400 that incorporates the teachings of the present disclosure. As shown, three separate nodes or current paths 402, 404, and 406 are connected in series similar to the architecture of resistor ladder network 200 as shown in FIG. 2 and described above. The combined signals through each of the current paths 402, 404, and 406 can be directed to output 408 for additional processing (e.g., through an operational amplifier as described above). It should be noted that three nodes or current paths 402, 404, and 406 is shown by way of example only. Depending upon the size of the digital input being converted, the number of nodes or current paths can be adjusted accordingly. For example, for an 8-bit DAC, 8 nodes or current paths can be included in the R/2R resistor ladder network.

As further shown in FIG. 4, each of current paths 402, 404, and 406 can include a feedforward capacitor C_{FF}. As described above, when combining outputs of various current paths for a single output, propagation delays through each successive current path can result in output errors and/or a low SFDR, especially at high speed sampling rates like 8 or 16-gigahertz sampling rates. By providing each current path 402, 404, and 406 with a feedforward capacitor C_{FF}, the propagation delay can be reduced or eliminated (depending upon the total number of bits in the DAC), and the SFDR can be improved. Operationally, the R/2R resistor ladder network can be considered an RC delay line, with the total R value set by the physical resistors of the R/2R resistor ladder network and the total C value set by the parasitic capacitance of any interconnects, resistors, and bit cell switches. By incorporating a bridging capacitance larger than the parasitic capacitance at each current path (and connected across each of the series R resistors as shown in FIG. 4), variation in delay and dispersion of each bit cell to the output (i.e., the contribution of the output signal from each current path) is lowered.

As noted above, in an R/2R resistor ladder network, the values of the R and 2R resistors can be selected to balance the resistive ratios in the resistor ladder network. In certain implementations, R can be selected from about 5 ohms to about 50 ohms. Similarly, 2R can be selected from about 10 ohms to about 100 ohms. In a certain implementation, similar to the example as described above, R can be selected as 25 ohms and 2R can be selected as 50 ohms.

In some examples, the feedforward capacitors throughout the R/2R resistor ladder network can have the same value. As the R values are constant throughout the ladder, it may be advantageous to maintain a constant C_{FF} value. For example, the C_{FF} value may be selected based upon the size of the R value. To continue the above example, if the R value is 25 ohms, the C_{FF} value may be between 25 and 75 femtofarads. In certain implementations, the C_{FF} value may be 60 femtofarads. In other examples, the C_{FF} value may be between 10 and 100 femtofarads.

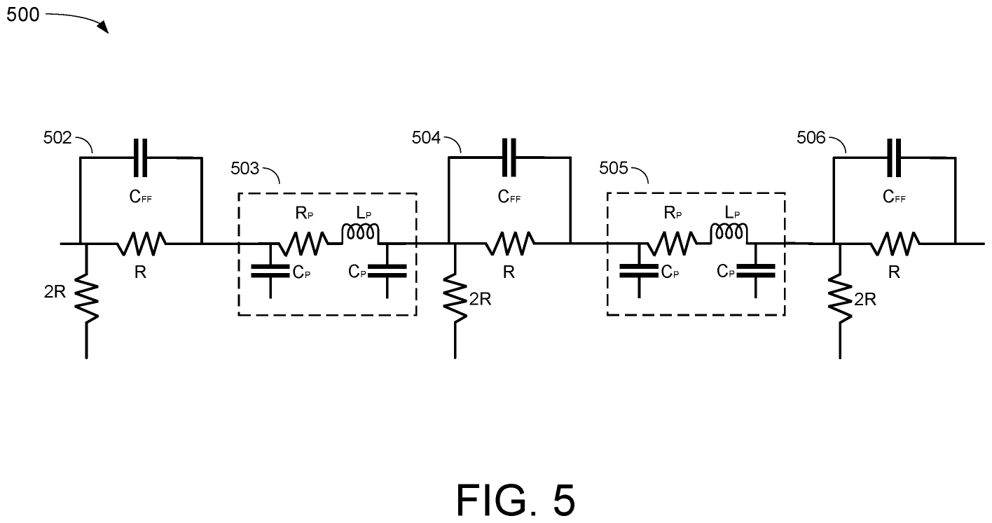

In certain implementations, the capacitive value of the feedforward capacitors can be selected to reduce the RC delay that is in part exacerbated by the parasitic capacitance in an R/2R resistor ladder network. This idea is discussed in greater detail in regard to FIG. 5 below.

As noted above, each feedforward capacitor in the R/2R resistor ladder network can have the same capacitance (e.g., 60 femtofarads). However, this is provided by way of example only. In certain implementations, each feedforward capacitor in the R/2R resistor ladder network can have a different value chosen from, for example, between 25 and 75 femtofarads. Varying the capacitance for each feedforward capacitor can provide an additional technique for varying the time that each current path through the R/2R resistor ladder network arrives at the output at the same time.

FIG. 5 provides additional detail on the circuit as shown in FIG. 4 by providing additional modeling of the transmission line. For example, FIG. 5 illustrates a similar R/2R resistor ladder network 500 as shown in, for example, FIG. 4. However, as shown in FIG. 5, the individual parasitic elements of the R/2R resistor ladder network 500 as illustrated as generic circuit element symbols.

The R/2R resistor ladder network 500 includes three individual nodes or current paths 502, 504, and 506. Similar to the above discussion, the three nodes or current paths 502,504, and 506 are shown by way of example only and, depending upon the size of the DAC, can varying based upon the intended application of the R/2R resistor ladder network 500.

Referring again to FIG. 5, between each of the current paths 502, 504, and 506 is a segment of transmission line. More specifically, transmission line 503 is positioned between current paths 502 and 504, and transmission line 505 is positioned between current paths 504 and 506.

As noted above, in an electrical network or circuit, various components contribute to an overall parasitic effect on the network. For example, a wire such as a transmission line has a parasitic resistance directly related to the wire's length and diameter/cross-sectional area. Similarly, a resistor has an associated resistance but also includes an unwanted parasitic capacitance. As shown in FIG. 5, for circuit optimization and reduction of overall parasitic elements, each portion of transmission line 503 and 505 can be modeled as including a parasitic resistance R_{P}, a parasitic induction L_{P}, and parasitic capacitance C_{P}. These parasitic elements can result from the geometry of wire used for the interconnects (e.g., length, thickness, and width), wiring layout, size and positioning of circuit elements, and other design choices made when designing the R/2R resistor ladder network (or other components of the DAC that may be positioned close to the R/2R resistor ladder network). By including and sizing the feedforward capacitors appropriately (e.g., by modeling the circuit and determining what the parasitic capacitance for the circuit will be and selecting the size of the feedforward capacitors accordingly), the overall propagation delay throughout the R/2R resistor ladder network can be reduced, the propagation delays through the R/2R network can be equalized, and the SFDR of the can be improved. For example, the capacitance of the feedforward capacitor (e.g., 60 femtofarads) can be selected such that the parasitic capacitance in the R/2R resistor ladder network is counteracted.

The techniques as described herein can be implemented in DACs designed for various implementations and applications. For example, the techniques as described herein can be implemented in DACs for wideband radio frequency communication systems, intermediate frequency signal processing systems, general purpose broadband telecommunications including wired and wireless communications, instrumentation, radar, and other similar applications where high-speed digital-to-analog conversion is beneficial.

### Further Example Embodiments

The following examples pertain to further embodiments, from which numerous permutations and configurations will be apparent.

Example 1 includes a digital-to-analog converter (DAC) including input logic circuitry configured to receive a multi-bit input signal and process the multi-bit input signal to produce a plurality of processed input signals and a resistor ladder network operably coupled to the input logic circuitry and configured to receive the plurality of processed input signals, the resistor ladder network comprising a plurality of current paths, each of the current paths corresponding to one bit of the multi-bit input signal. Each of the current paths includes a current switch operably controlled by one of the plurality of processed input signals, a first resistor in series with the current switch, a second resistor in series with the first resistor, and a feedforward capacitor in parallel with the second resistor. The DAC further includes an output operably coupled to each of the plurality of current paths, the output configured to output an analog output signal that corresponds to the multi-bit input signal.

Example 2 includes the subject matter of Example 1, wherein the first resistor comprises a resistance that is double a resistance of the second resistor.

Example 3 includes the subject matter of Example 1 or 2, wherein the feedforward capacitor is sized to reduce delay through each of the current paths in the resistor ladder network.

Example 4 includes the subject matter of any of the preceding Examples, wherein the first resistor comprises a resistance of about 50 ohms, the second resistor comprises a resistance of about 25 ohms, and the feedforward capacitor comprises a capacitance of about 60 femtofarads.

Example 5 includes the subject matter of any of the preceding Examples, wherein the first resistor comprises a resistance of about 10 ohms to about 100 ohms, the second resistor comprises a resistance of about 5 ohms to about 50 ohms, and the feedforward capacitor comprises a capacitance of about 10 femtofarads to about 75 femtofarads.

Example 6 includes the subject matter of any of the preceding Examples, wherein the DAC is configured to operate at a gigahertz sampling rate.

Example 7 includes the subject matter of any of the preceding Examples, wherein resistive values for the first resistor and the second resistor are selected to compensate for parasitic elements from circuit elements in the resistor ladder network.

Example 8 includes the subject matter of any of the preceding Examples, wherein each feedforward capacitor in each current path comprises a substantially identical capacitance.

Example 9 includes an electrical circuit including a resistor ladder network configured to receive a plurality of processed input signals generated from a multi-bit input signal, the resistor ladder network comprising a plurality of current paths, each of the current paths corresponding to one bit of the multi-bit input signal. Each of the current paths includes a current switch operably controlled by one of the plurality of processed input signals, a first resistor in series with the current switch, a second resistor in series with the first resistor, and a feedforward capacitor in parallel with the second resistor.

Example 10 includes the subject matter of Example 9, wherein the first resistor comprises a resistance that is double a resistance of the second resistor.

Example 11 includes the subject matter of Example 9 or 10, wherein the feedforward capacitor is sized to reduce delay through each of the current paths in the resistor ladder network.

Example 12 includes the subject matter of any of Examples 9-11, wherein the first resistor comprises a resistance of about 50 ohms, the second resistor comprises a resistance of about 25 ohms, and the feedforward capacitor comprises a capacitance of about 60 femtofarads.

Example 13 includes the subject matter of any of Examples 9-12, wherein the first resistor comprises a resistance of about 10 ohms to about 100 ohms, the second resistor comprises a resistance of about 5 ohms to about 50 ohms, and the feedforward capacitor comprises a capacitance of about 10 femtofarads to about 75 femtofarads.

Example 14 includes the subject matter of any of Examples 9-13, wherein resistive values for the first resistor and the second resistor are selected to compensate for parasitic elements from circuit elements in the resistor ladder network.

Example 15 includes the subject matter of any of Examples 9-14, wherein each feedforward capacitor in each current path comprises a substantially identical capacitance.

Example 16 includes a digital to analog converter (DAC), the DAC including an input to receive a digital input signal, an output to output an analog signal corresponding to the digital input signal and a resistor ladder network operatively coupled between the input and the output, the resistor ladder network comprising a plurality of current paths, each of the current paths corresponding to a bit of the digital input signal. Each of the current paths includes a switch operably controlled by a corresponding bit of the digital input signal, a first resistor in series with the switch, a second resistor in series with the first resistor, and a feedforward capacitor in parallel with the second resistor.

Example 17 includes the subject matter of Example 16, wherein the first resistor comprises a resistance that is double a resistance of the second resistor.

Example 18 includes the subject matter of Example 16 or 17, wherein the feedforward capacitor is sized to reduce delay through each of the current paths in the resistor ladder network.

Example 19 includes the subject matter of any of Examples 16-18, wherein the first resistor comprises a resistance of about 10 ohms to about 100 ohms, the second resistor comprises a resistance of about 5 ohms to about 50 ohms, and the feedforward capacitor comprises a capacitance of about 10 femtofarads to about 75 femtofarads.

Example 20 includes the subject matter of any of Examples 16-19, wherein the DAC has a sampling rate of 8 GHz or higher, and a resolution of 8-bits or higher.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. In addition, various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications. It is intended that the scope of the present disclosure be limited not be this detailed description, but rather by the claims appended hereto. Future filed applications claiming priority to this application may claim the disclosed subject matter in a different manner, and may generally include any set of one or more elements as variously disclosed or otherwise demonstrated herein.

1. A digital-to-analog converter (DAC) comprising:
input logic circuitry configured to receive a multi-bit input signal and process the multi-bit input signal to produce a plurality of processed input signals;
a resistor ladder network operably coupled to the input logic circuitry and configured to receive the plurality of processed input signals, the resistor ladder network comprising a plurality of current paths, each of the current paths corresponding to one bit of the multi-bit input signal, wherein each of the current paths comprises:
a current switch operably controlled by one of the plurality of processed input signals,
a first resistor in series with the current switch,
a second resistor in series with the first resistor, and
a feedforward capacitor in parallel with the second resistor, wherein each feedforward capacitor in each current path comprises a capacitor value different from the capacitor value of each other feedforward capacitor; and
an output operably coupled to each of the plurality of current paths, the output configured to output an analog output signal that corresponds to the multi-bit input signal.

2. The DAC of claim 1, wherein the first resistor comprises a resistance that is double a resistance of the second resistor.

3. The DAC of claim 1, wherein the feedforward capacitor is sized to reduce delay through each of the current paths in the resistor ladder network.

4. The DAC of claim 1, wherein the first resistor comprises a resistance of about 50 ohms, the second resistor comprises a resistance of about 25 ohms.

5. The DAC of claim 1, wherein the first resistor comprises a resistance of about 10 ohms to about 100 ohms, the second resistor comprises a resistance of about 5 ohms to about 50 ohms, and the feedforward capacitor comprises a capacitance of about 10 femtofarads to about 75 femtofarads.

6. The DAC of claim 1, wherein the DAC is configured to operate at a gigahertz sampling rate.

7-8. (canceled)

9. An electrical circuit comprising:
a resistor ladder network configured to receive a plurality of processed input signals generated from a multi-bit input signal, the resistor ladder network comprising a plurality of current paths, each of the current paths corresponding to one bit of the multi-bit input signal, wherein each of the current paths includes
a current switch operably controlled by one of the plurality of processed input signals,
a first resistor in series with the current switch,
a second resistor in series with the first resistor, and
a feedforward capacitor in parallel with the second resistor, wherein each feedforward capacitor in each current path comprises a capacitor value different from the capacitor value of each other feedforward capacitor.

10. The electrical circuit of claim 9, wherein the first resistor comprises a resistance that is double a resistance of the second resistor.

11. The electrical circuit of claim 9, wherein the feedforward capacitor is sized to reduce delay through each of the current paths in the resistor ladder network.

12. The electrical circuit of claim 9, wherein the first resistor comprises a resistance of about 50 ohms, the second resistor comprises a resistance of about 25 ohms.

13. The electrical circuit of claim 9, wherein the first resistor comprises a resistance of about 10 ohms to about 100 ohms, the second resistor comprises a resistance of about 5 ohms to about 50 ohms, and the feedforward capacitor comprises a capacitance of about 10 femtofarads to about 75 femtofarads.

14-15. (canceled)

16. A digital to analog converter (DAC), comprising:
an input to receive a digital input signal;
an output to output an analog signal corresponding to the digital input signal; and
a resistor ladder network operatively coupled between the input and the output, the resistor ladder network comprising a plurality of current paths, each of the current paths corresponding to a bit of the digital input signal, and wherein-each of the current paths including
a switch operably controlled by a corresponding bit of the digital input signal,
a first resistor in series with the switch,
a second resistor in series with the first resistor, and
a feedforward capacitor in parallel with the second resistor, wherein each feedforward capacitor in each current path comprises a capacitor value different from the capacitor value of each other feedforward capacitor.

17. The DAC of claim 16, wherein the first resistor comprises a resistance that is double a resistance of the second resistor.

18. The DAC of claim 16, wherein the feedforward capacitor is sized to reduce delay through each of the current paths in the resistor ladder network.

19. The DAC of claim 16, wherein the first resistor comprises a resistance of about 10 ohms to about 100 ohms, the second resistor comprises a resistance of about 5 ohms to about 50 ohms, and the feedforward capacitor comprises a capacitance of about 10 femtofarads to about 75 femtofarads.

20. The DAC of claim 16, wherein the DAC has a sampling rate of 8 GHz or higher, and a resolution of 8-bits or higher.

21. The DAC of claim 1, wherein the resistor ladder network further a transmission line, wherein the transmission line includes a parasitic resistance R_{P}, a parasitic induction L_{P}, and parasitic capacitance C_{P}.

22. The electrical circuit of claim 9, wherein the resistor ladder network includes a transmission line, wherein the transmission line includes a parasitic resistance R_{P}, a parasitic induction L_{P}, and parasitic capacitance C_{P}.
